(19) United States
(12) Patent Application Publication
(10) Pub. No.: US 2025/0285921 A1
(43) Pub. Date: Sep. 11, 2025

(54) METHOD FOR MANUFACTURING SEMICONDUCTOR DEVICE

(71) Applicant: Resonac Corporation, Minato-ku, Tokyo (JP)

(72) Inventors: Yuki MIYAMOTO, Minato-ku, Tokyo (JP); Haemil CHOI, Minato-ku, Tokyo (JP); Yukihiro IWANAGA, Minato-ku, Tokyo (JP); Masayuki WADA, Minato-ku, Tokyo (JP); Keiichi SAKAMOTO, Minato-ku, Tokyo (JP); Masahito WATANABE, Minato-ku, Tokyo (JP); Hidekazu KONDO, Minato-ku, Tokyo (JP); Koichi SAITO, Minato-ku, Tokyo (JP)

(21) Appl. No.: 18/860,125

(22) PCT Filed: Oct. 6, 2023
(86) PCT No.: PCT/JP2023/036619

§ 371 Date: Oct. 25, 2024

(30) Foreign Application Priority Data
Oct. 11, 2022 (JP) 2022-163413

(51) Int. Cl. H01L 21/78; H01L 21/304

(52) U.S. Cl. CPC H01L 21/78; H01L 21/304

(57) ABSTRACT

The present disclosure relates to a method for manufacturing a semiconductor device, the method including: a first laminate manufacturing step of manufacturing a first laminate including a semiconductor wafer, a resin layer containing a resin reduced in molecular weight by reaction with water, and a base material layer; a second laminate manufacturing step of subjecting the semiconductor wafer of the first laminate to back-surface grinding to manufacture a second laminate; and a third laminate manufacturing step of removing the base material layer of the second laminate to manufacture a third laminate including the semiconductor wafer subjected to back-surface grinding and the resin layer.

### TECHNICAL FIELD

The present disclosure relates to a method for manufacturing a semiconductor device.

### TECHNICAL FIELD

In the manufacture of a semiconductor device, a pattern is formed on one surface (front surface) of a semiconductor wafer, and the semiconductor wafer is generally subjected to a back-surface grinding (back grinding) process of grinding the other surface (back surface) with a back grinder or the like until a predetermined thickness is obtained. In a back-surface grinding process, for the purpose of protecting a semiconductor wafer, a back grinding tape is generally bonded to the semiconductor wafer to grind the back surface (for example, Patent Literature 1).

### CITATION LIST

### Patent Literature

### Patent Literature 1: Japanese Unexamined Patent Publication No. 2010-034379

### SUMMARY OF INVENTION

### Technical Problem

An object of the present disclosure is to provide a novel method for manufacturing a semiconductor device including a step of grinding a back surface of a semiconductor wafer.

### Solution to Problem

The present disclosure provides a method for manufacturing a semiconductor device as the following [1] to [3].
[1] A method for manufacturing a semiconductor device, the method including: a first laminate manufacturing step of manufacturing a first laminate including a semiconductor wafer, a resin layer containing a resin reduced in molecular weight by reaction with water, and a base material layer; a second laminate manufacturing step of subjecting the semiconductor wafer of the first laminate to back-surface grinding to manufacture a second laminate; and a third laminate manufacturing step of removing the base material layer of the second laminate to manufacture a third laminate including the semiconductor wafer subjected to back-surface grinding and the resin layer.
[2] The method for manufacturing a semiconductor device according to [1], further including: a resin-layer-piece-attached semiconductor chip manufacturing step of manufacturing a diced resin-layer-piece-attached semiconductor chip by dicing the third laminate.
[3] The method for manufacturing a semiconductor device according to [2], further including: a resin layer piece removing step of reacting the resin in a resin layer piece of the resin-layer-piece-attached semiconductor chip with water to remove the resin layer piece from the resin-layer-piece-attached semiconductor chip.

### Advantageous Effects of Invention

According to the present disclosure, there is provided a novel method for manufacturing a semiconductor device including a step of grinding a back surface of a semiconductor wafer.

### BRIEF DESCRIPTION OF DRAWINGS

FIG. 1 is a schematic cross-sectional view for explaining an embodiment of a method for manufacturing a semiconductor device, and FIGS. 1(a), 1(b), 1(c), and 1(d) are views illustrating respective steps.

FIG. 2 is a schematic cross-sectional view for explaining an embodiment of a method for manufacturing a semiconductor device, and FIGS. 2(a), 2(b), and 2(c) are views illustrating respective steps.

FIG. 3 is a schematic cross-sectional view for explaining an embodiment of a method for manufacturing a semiconductor device, and FIGS. 3(a), 3(b), and 3(c) are views illustrating respective steps.

### DESCRIPTION OF EMBODIMENTS

Hereinafter, the present embodiment will be described in detail with reference to the drawings. However, the present disclosure is not limited to the following embodiments. In the following embodiments, the components (including steps and the like) are not essential unless otherwise specified. The same or corresponding portions are denoted by the same reference numerals, and redundant description will be omitted. The positional relationship such as up, down, left, and right is based on the positional relationship illustrated in the drawings unless otherwise specified. The sizes of the components in the drawings are conceptual, and the relative relationship between the sizes of the components is not limited to that illustrated in the drawings.

The same applies to numerical values and ranges thereof in the present disclosure, and the present disclosure is not limited thereto. In the present specification, a numerical range indicated using “to” indicates a range including numerical values described before and after “to” as a minimum value and a maximum value, respectively. In the numerical ranges described in stages in the present specification, the upper limit value or the lower limit value described in one numerical range may be replaced with the upper limit value or the lower limit value of the numerical range described in another stage. In the numerical range described in the present specification, the upper limit value or the lower limit value of the numerical range may be replaced with a value shown in examples.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as an intended action of the step is achieved.

In the present specification, “(meth) acryloyl” means at least one of acryloyl and methacryloyl. In the present specification, the “(poly) oxyalkylene group” means at least one of an oxyalkylene group and a polyoxyalkylene group. The polyoxyalkylene group is a group in which two or more alkylene groups are linked by an ether bond. The same applies to other similar expressions such as “(poly) oxyethylene group”.

The components and materials exemplified in the present specification may be used singly or in combination of two or more kinds thereof unless otherwise specified.

### [Method for Manufacturing Semiconductor Device]

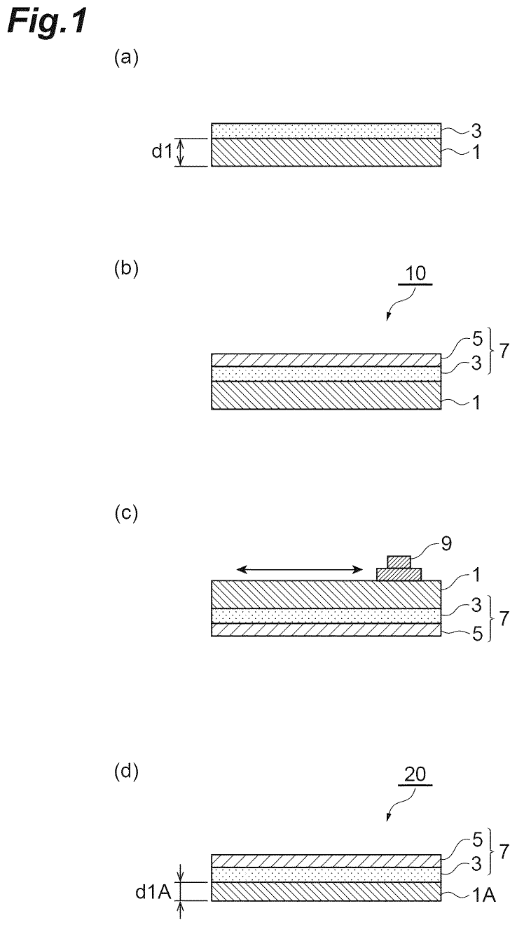

The method for manufacturing a semiconductor device according to an embodiment relates to a method for manufacturing a semiconductor device including a step of grinding a back surface of a semiconductor wafer. The method for manufacturing the semiconductor device includes a first laminate manufacturing step, a second laminate manufacturing step, and a third laminate manufacturing step. The method for manufacturing the semiconductor device may further include a resin-layer-piece-attached semiconductor chip manufacturing step, and may further include a resin layer piece removing step. FIGS. 1, 2, and 3 are schematic cross-sectional views for explaining an embodiment of a method for manufacturing a semiconductor device.

### <First Laminate Manufacturing Step>

In this step, a first laminate 10 including a semiconductor wafer 1, a resin layer 3 containing a resin (hereinafter, also referred to as “resin A”) reduced in molecular weight by reaction with water, and a base material layer 5 is manufactured. The resin A is a resin having a property of improving solubility in water by being reduced in molecular weight by reaction with water.

In one embodiment, the resin A may be a resin containing an ester bond and a basic functional group. The resin containing an ester bond and a basic functional group is a resin that undergoes a hydrolysis reaction of the ester bond in the presence of the basic functional group by reaction with water to reduce the molecular weight. The resin layer 3 can be formed, for example, by solidifying the resin A or by reacting and solidifying a precursor of the resin A.

Examples of the basic functional group in the resin A include —NH— and —NH₂.

The resin A can be formed using a resin layer forming material containing a compound A containing two or more first groups and having an ester bond and a compound B containing two or more second groups capable of forming a bond with the first group and capable of forming a resin containing an ester bond and a basic functional group by reaction with the compound A.

The compound A may contain an ester bond in the first group, and may contain an ester bond as a functional group different from the first group. Examples of the first group in the compound A include a (meth) acryloyloxy group; Isocyanate group; Cyclic ether group (oxirane group (oxiranyl group, epoxy group), oxetane group (oxetanyl group), tetrahydrofuryl group, tetrahydropyranyl group, and the like); an ethylenically unsaturated group (C═C). The number of the first groups in a compound A1 molecule may be 2 or more, 3 or more, or 4 or more, and may be 10 or less, 8 or less, 6 or less, or 5 or less.

The compound A may be a compound containing two or more first groups and a linking group linking these first groups. The linking group may include, for example, a (poly)oxyalkylene group. Examples of the (poly)oxyalkylene group include a (poly) oxyethylene group. The linking group may contain at least one skeleton selected from the group consisting of a pentaerythritol skeleton, a trimethylolpropane skeleton, and an isocyanurate skeleton.

The molecular weight or number average molecular weight of the compound A may be 150 or more, 500 or more, or 1,000 or more, and may be 50,000 or less, 10,000 or less, or 2,000 or less. In the present specification, the “number average molecular weight” is a polystyrene equivalent value using a calibration curve by standard polystyrene by a gel permeation chromatography method (GPC).

The compound A may be a compound containing two first groups or a compound containing two (meth) acryloyloxy groups. In the case of containing two first groups, the time until the resin A is dissolved in water tends to be longer than in the case of containing two first groups or the like.

The compound A containing two (meth) acryloyloxy groups may contain a structure represented by the following Expression (a1).

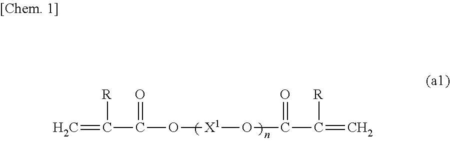

In Expression (a1), R represents a hydrogen atom or a methyl group. X¹ represents an alkylene group. The number of carbon atoms of the alkylene group may be, for example, 2 or more, and may be 10 or less, 6 or less, 4 or less, or 3 or less. The alkylene group may be, for example, an ethylene group (—CH₂—CH₂—).

n represents an integer of 1 or more. n may be, for example, 1 or more, 5 or more, 10 or more, 15 or more, or 20 or more, and may be 50 or less, 45 or less, 40 or less, 35 or less, 30 or less, or 25 or less.

Examples of commercially available products of the compound A containing two (meth) acryloyloxy groups include NK ester A-1000 (manufactured by Shin-Nakamura Chemical Co., Ltd. chemical name: polyethylene glycol #1000 diacrylate), A-600 (manufactured by Shin-Nakamura Chemical Co., Ltd., chemical name: polyethylene glycol #600 diacrylate), A-400 (manufactured by Shin-Nakamura Chemical Co., Ltd., chemical name: polyethylene glycol #400 diacrylate), A-200 (manufactured by Shin-Nakamura Chemical Co., Ltd., chemical name: polyethylene glycol #200 diacrylate), 2G (manufactured by Shin-Nakamura Chemical Co., Ltd., chemical name: diethylene glycol dimethacrylate), 3G (manufactured by Shin-Nakamura Chemical Co., Ltd., chemical name: triethylene glycol dimethacrylate), 4G (manufactured by Shin-Nakamura Chemical Co., Ltd., chemical name: polyethylene glycol #200 dimethacrylate), 9G (manufactured by Shin-Nakamura Chemical Co., Ltd., chemical name: polyethylene glycol #400 dimethacrylate), 14G (manufactured by Shin-Nakamura Chemical Co., Ltd., chemical name: polyethylene glycol #600 dimethacrylate), 23G (manufactured by Shin-Nakamura Chemical Co., Ltd., chemical name: polyethylene glycol #1000 dimethacrylate), light acrylate 3EG-A (manufactured by Kyoeisha Chemical Co., Ltd., chemical name: triethylene glycol dimethacrylate), light acrylate 4EG-A (manufactured by Kyoeisha Chemical Co., Ltd., chemical name: polyethylene glycol #200 diacrylate), light acrylate 9EG-A (manufactured by Kyoeisha Chemical Co., Ltd., chemical name: polyethylene glycol #400 diacrylate), light acrylate 14EG-A (manufactured by Kyoeisha Chemical Co., Ltd., chemical name: polyethylene glycol #600 diacrylate), light ester EG (manufactured by Kyoeisha Chemical Co., Ltd., chemical name: ethylene glycol dimethacrylate), light ester 2EG (manufactured by Kyoeisha Chemical Co., Ltd., chemical name: diethylene glycol dimethacrylate), light ester 3EG (manufactured by Kyoeisha Chemical Co., Ltd., chemical name: triethylene glycol dimethacrylate), light ester 4EG (manufactured by Kyoeisha Chemical Co., Ltd., chemical name: polyethylene glycol #200 dimethacrylate), light ester 9EG (manufactured by Kyoeisha Chemical Co., Ltd., chemical name: polyethylene glycol #400 dimethacrylate), light ester 14EG (manufactured by Kyoeisha Chemical Co., Ltd., chemical name: polyethylene glycol #600 dimethacrylate), fancryl FA-222A (manufactured by Showa Denko Materials Co., Ltd., chemical name: diethylene glycol diacrylate), fancryl FA-232A (manufactured by Showa Denko Materials Co., Ltd., chemical name: diethylene glycol diacrylate), fancryl FA-220A, FA-230A, FA-240A, FA-260A, FA-2100A, FA-2200A (a1l manufactured by Showa Denko Materials Co., Ltd., chemical name: polyethylene glycol diacrylate), fancryl FA-222M (manufactured by Showa Denko Materials Co., Ltd., chemical name: diethylene glycol dimethacrylate), fancryl FA-232M (manufactured by Showa Denko Materials Co., Ltd., chemical name: diethylene glycol dimethacrylate), fancryl FA-220M, and FA-230M, FA-240M, FA-260M, FA-2100M, and FA-2200M (a1l manufactured by Shin-Nakamura Chemical Co., Ltd., chemical name: polyethylene glycol dimethacrylate).

The compound A may be a compound containing three or more first groups, or may be a compound containing three or more (meth) acryloyloxy groups.

The compound A containing three or more (meth) acryloyloxy groups may be, for example, a compound represented by the following Expression (a2).

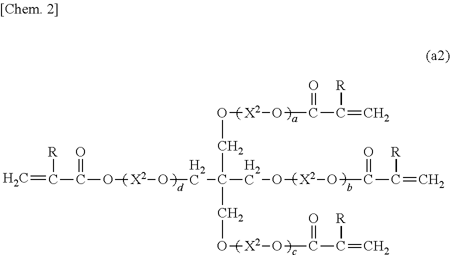

In Expression (a2), R represents a hydrogen atom or a methyl group, and X² represents an alkylene group. a, b, c, and d each independently represent 0 or an integer of 1 or more. A plurality of Rs may be the same or different. The number of carbon atoms of the alkylene group represented by X² may be 2 or more, and may be 10 or less, 6 or less, or 3 or less. The alkylene group represented by X² may be, for example, an ethylene group (—CH₂—CH₂—). In a case where there are a plurality of X²s, they may be the same or different. The sum a+b+c+d of a, b, c, and d may be, for example, 1 or more, 5 or more, 10 or more, 15 or more, 20 or more, 25 or more, or 30 or more, and may be 60 or less, 55 or less, 50 or less, 45 or less, or 40 or less.

Examples of commercially available products of the compound A containing three or more (meth) acryloyloxy groups include NK ester ATM-35E (manufactured by Shin-Nakamura Chemical Co., Ltd., chemical name: ethoxylated pentaerythritol tetraacrylate), NK ester A-TMPT-9EO (manufactured by Shin Nakamura Chemical Co., Ltd., chemical name: ethoxylated trimethylolpropane triacrylate), NK ester AT-20E (manufactured by Shin Nakamura Chemical Co., Ltd., chemical name: ethoxylated trimethylolpropane triacrylate), NK ester A-GLY-3E (manufactured by Shin-Nakamura Chemical Co., Ltd., chemical name: ethoxylated glycerin triacrylate), NK ester A-GLY-9E (manufactured by Shin-Nakamura Chemical Co., Ltd., chemical name: ethoxylated glycerin triacrylate), NK ester A-GLY-20E (manufactured by Shin-Nakamura Chemical Co., Ltd., chemical name: ethoxylated glycerin triacrylate), and A-DPH-12E (manufactured by Shin-Nakamura Chemical Co., Ltd., chemical name: ethoxylated dipentaerythritol polyacrylate).

The compound A may be a compound exhibiting solubility in water. The solubility of the compound A in 100 g of water at 25° C. may be 1 g or more, 5 g or more, or 10 g or more. The upper limit of the solubility is not particularly limited.

The content of the compound A may be 80 parts by mass or more, 85 parts by mass or more, or 90 parts by mass or more, and may be 99 parts by mass or less, 95 parts by mass or less, or 90 parts by mass or less, with respect to 100 parts by mass with respect to the total content of the compound A and the compound B.

The second group in the compound B is appropriately selected according to the type of the first group. The combination of the first group and the second group may be, for example, a combination of at least one first group selected from the group consisting of a (meth) acryloyloxy group, an isocyanate group, a cyclic ether group (oxirane group (oxiranyl group, epoxy group), oxetane group (oxetanyl group), tetrahydrofuryl group, tetrahydropyranyl group, and the like), and an ethylenically unsaturated group (C═C) and at least one second group selected from the group consisting of an amino group (—NH—, —NH₂) and a mercapto group (—SH), and may be a combination of a (meth) acryloyloxy group and an amino group (—NH—, —NH₂).

The number of the second groups in a compound B1 molecule is 2 or more, and may be 10 or less, 8 or less, 6 or less, 4 or less, or 3 or less, and may be 2. The number of the second groups in the compound B1 molecule may be the same as or different from the number of the first groups in the compound A1 molecule, and may be smaller than the number of the first groups in the compound A1 molecule.

The compound B may contain a functional group other than the second group. Examples of the functional group other than the second group include an alkylene group and —NH-(imino group).

The compound B may be a compound containing two or more second groups and an alkylene group, a compound containing two or more second groups, an alkylene group, and —NH—, or a compound containing two or more amino groups, an alkylene group, and —NH—.

The compound B may be, for example, a compound represented by the following Expression (b).

H₂N—Y—NH₂(b) [Chem. 3]

Y represents a divalent group including an alkylene group. The divalent group containing an alkylene group represented by Y may contain —NH—. The compound B may be, for example, a compound represented by the following Expression (b1).

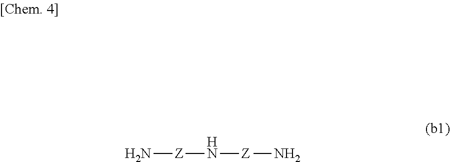

In Expression (b), Z represents an alkylene group. The number of carbon atoms in the alkylene group may be 1 or more, 2 or more, or 3 or more, and may be 10 or less, 8 or less, 6 or less, or 4 or less.

Examples of the compound B include bis(3-aminopropyl) amine, norbornanediamine, ethylenediamine, diethylenetriamine, triethylenetetramine, tetraethylenepentamine, polyetheramine, 4,4′-diaminodiphenylsulfone, 3,3′-diaminodiphenylsulfone, 4,4′-diaminodiphenyl ether, 1,3-bis(3-aminophenoxy)benzene, bisaniline, aminobenzylamine, and polyoxypropylenediamine.

The compound B may be a compound exhibiting solubility in water. The solubility of the compound B in 100 g of water at 25° C. may be 1 g or more, 5 g or more, or 10 g or more. The upper limit of the solubility is not particularly limited.

The ratio of the number of moles of the compound B to the number of moles of the compound A (number of moles of the compound B/number of moles of the compound A) may be 0.20 or more, 0.40 or more, 0.60 or more, 0.80 or more, or 1.00 or more. The ratio of the number of moles of the compound B to the number of moles of the compound A (number of moles of the compound B/number of moles of the compound A) may be, for example, 10.00 or less, 8.00 or less, 6.00 or less, 4.00 or less, 3.00 or less, 2.50 or less, or 2.20 or less.

The content of the compound B may be 1 part by mass or more, 5 parts by mass or more, 8 parts by mass or more, or 10 parts by mass or more, with respect to 100 parts by mass of the total content of the compound A and the compound B. The content of the compound B may be 20 parts by mass or less, 15 parts by mass or less, 10 parts by mass or less, or 8 parts by mass or less, with respect to 100 parts by mass of the total content of the compound A and the compound B.

The resin A which is a reaction product of the compound A and the compound B can be obtained by mixing or kneading these compounds. Mixing and kneading can be performed by appropriately combining a disperser such as a normal stirrer, a mixing machine, a three-roll mill, a ball mill, or a bead mill.

The reaction may proceed while heating as necessary. The reaction temperature when reacting the compound A and the compound B may be, for example, 0° C. or higher, 10° C. or higher, or 20° C. or higher, and may be 100° C. or lower, 85° C. or lower, or 70° C. or lower. The time for holding at the reaction temperature may be, for example, 1.0 minutes or more, and may be 60 minutes or less, 30 minutes or less, 10 minutes or less, 5 minutes or less, or 3 minutes or less.

The resin layer 3 may further contain components (other components) other than the resin A. Examples of other components include additives such as a plasticizer; an adhesiveness imparting agent such as tackifier; an antioxidant; Leuco dye; a sensitizer; an adhesion improver such as a coupling agent; a polymerization inhibitor; a light stabilizer; an antifoaming agent; a filler; a chain transfer agent; a thixotropy imparting agent; a flame retardant; a mold release agent; a surfactant; a lubricant; an antistatic agent. As these additives, known additives can be used. In a case where the resin layer 3 contains other components, the total content of the other components may be 0 to 95 mass %, 0.01 to 50 mass %, or 0.1 to 10 mass % based on the total amount of the resin layer 3.

The resin A may be diluted with an organic solvent and used as a varnish. Examples of the organic solvent include aromatic hydrocarbons such as toluene, xylene, mesitylene, cumene, and p-cymene; aliphatic hydrocarbon such as hexane and heptane; cyclic alkanes such as methylcyclohexane; cyclic ethers such as tetrahydrofuran and 1,4-dioxane; ketones such as acetone, methyl ethyl ketone, methyl isobutyl ketone, cyclohexanone, and 4-hydroxy-4 methyl-2-pentanone; esters such as methyl acetate, ethyl acetate, butyl acetate, methyl lactate, ethyl lactate, and γ-butyrolactone; carbonic acid esters such as ethylene carbonate and propylene carbonate; amides such as N,N-dimethylformamide, N,N-dimethylacetamide, and N-methyl-2 pyrrolidone (NMP). The content of the solid content in the varnish, that is, the content of components other than the organic solvent in the varnish may be 10 to 95 mass %, 15 to 70 mass %, or 20 to 50 mass % based on the total amount of the varnish.

The first laminate manufacturing step may include, for example, a step of preparing the semiconductor wafer 1, a step of forming the resin layer 3 containing the resin A on the semiconductor wafer 1 (see FIG. 1(a)), and a step of disposing the base material layer 5 on the resin layer 3 to manufacture the first laminate 10 (see FIG. 1(b)).

The first laminate manufacturing step is not limited to the above method, and may include, for example, a step of forming the resin layer 3 containing the resin A on the base material layer 5, and a step of manufacturing the first laminate 10 by arranging the laminate including the base material layer 5 and the resin layer 3 on the semiconductor wafer 1 such that the resin layer 3 is in contact with the semiconductor wafer 1 (see FIG. 1(b)). Examples of the method for disposing the laminate including the base material layer 5 and the resin layer 3 on the semiconductor wafer 1 include a method for bonding or laminating the laminate while heating or at room temperature.

Examples of the semiconductor wafer 1 include single crystal silicon, polycrystalline silicon, various ceramics, and compound semiconductors such as gallium arsenide. The semiconductor wafer 1 may have a circuit formation surface.

The thickness d1 of the semiconductor wafer 1 may be, for example, 10 to 1000 μm, 20 to 900 μm, or 30 to 800 μm.

As a method for forming the resin layer on the semiconductor wafer, for example, a method including applying a resin on the semiconductor wafer by a spin coating method, a slit coating method, or the like, and solidifying the applied resin to form the resin layer can be used. The resin layer may be disposed on a circuit formation surface on the semiconductor wafer, for example. The resin may be solidified under normal temperature conditions.

The thickness of the resin layer 3 may be, for example, 1 to 1000 μm, 3 to 500 μm, or 5 to 200 μm.

As the base material layer 5, a material that can be removed from the resin layer 3 in the third laminate manufacturing step can be used.

Examples of the base material layer 5 include a polyolefin film of polyethylene (PE), polypropylene (PP), or the like; a polyester film such as polyethylene terephthalate (PET), polybutylene terephthalate (PBT), and polyethylene naphthalate; a polyvinyl chloride (PVC) film; a polyimide (PI) film; a polyphenylene sulfide (PPS) film; an ethylene-vinyl acetate (EVA) film; a polytetrafluoroethylene (PTFE) film.

The thickness of the base material layer 5 may be, for example, 10 to 1000 μm, 30 to 500 μm, or 50 to 200 μm.

In this way, the first laminate 10 including the semiconductor wafer 1, the resin layer 3 containing the resin A, and the base material layer 5 in this order can be manufactured.

### <Second Laminate Manufacturing Step>

In this step, the semiconductor wafer 1 of the first laminate 10 is subjected to back-surface grinding to manufacture a second laminate 20 (see FIG. 1(c)). The base material layer 5 and the resin layer 3 of the first laminate 10 can be regarded as a back grinding tape 7 having the base material layer 5 and the resin layer 3 provided on the base material layer 5. It can be said that the back grinding tape 7 is attached to the semiconductor wafer 1 in the first laminate 10, and the first laminate 10 can be directly subjected to a back-surface grinding (back grinding) process.

The back-surface grinding of the semiconductor wafer 1 can be performed using a general back grinder. As illustrated in FIG. 1(d), the surface of the semiconductor wafer 1 opposite to the surface to which the back grinding tape 7 is attached is ground using, for example, a grinder 9 to make the semiconductor wafer 1 thinned.

The thickness d1A of the back-surface ground semiconductor wafer (semiconductor wafer 1A) is thinner than the thickness d1 of the semiconductor wafer 1, and may be, for example, 10 to 1000 μm, 20 to 900 μm, or 30 to 800 μm.

In this way, the second laminate 20 including the semiconductor wafer 1A, the resin layer 3 containing the resin A, and the base material layer 5 in this order can be manufactured.

### <Third Laminate Manufacturing Step>

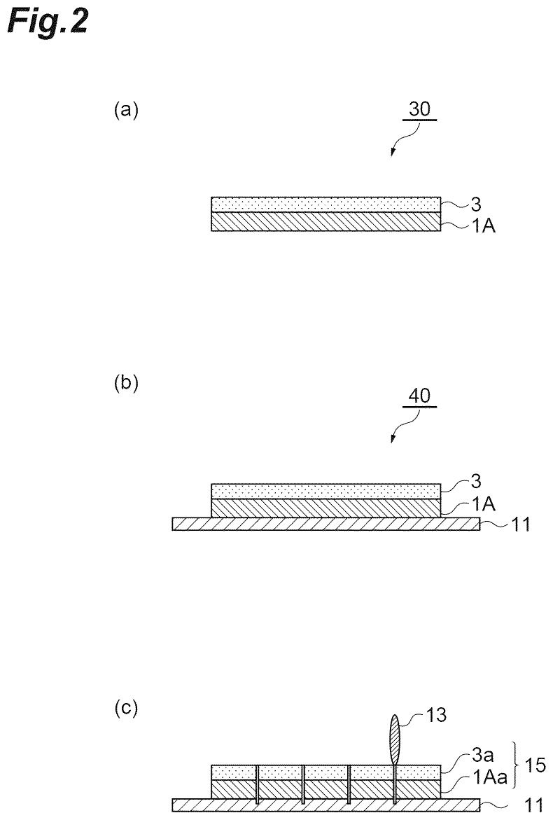

In this step, the base material layer 5 of the second laminate 20 is removed, and a third laminate 30 including the semiconductor wafer 1A and the resin layer 3 is manufactured (see FIG. 2(a)).

The method for removing the base material layer 5 from the second laminate 20 is not particularly limited, and it can be performed using a normal method. For example, the base material layer 5 can be removed from the second laminate 20 by using, as the base material layer 5, a material having adhesiveness on the surface in contact with the resin layer 3 and adjusting the degree of adhesiveness.

The resin layer 3 of the third laminate 30 can be used as a protective layer of the semiconductor wafer 1A after the next process. Since the resin layer 3 contains a resin which is reduced in molecular weight by reaction with water and as a result, whose solubility in water is improved, the resin layer can be easily removed using an aqueous solvent in the step after being used as a protective layer.

### <Resin-Layer-Piece-Attached Semiconductor Chip Removing Step>

In this step, the third laminate 30 is diced to manufacture diced resin-layer-piece-attached semiconductor chips 15.

The resin-layer-piece-attached semiconductor chip manufacturing step may include, for example, a step of preparing a laminate 40 including a dicing tape 11, a semiconductor wafer 1A, and a resin layer 3 in this order (see FIG. 2(b)), and a step of dicing at least the semiconductor wafer 1A and the resin layer 3 in the laminate 40 to obtain the resin-layer-piece-attached semiconductor chip 15 that has been divided (see FIG. 2(c)).

Examples of the dicing tape 11 include plastic films such as a polytetrafluoroethylene film, a polyethylene terephthalate film, a polyethylene film, a polypropylene film, a polymethylpentene film, and a polyimide film. The dicing tape 11 may be subjected to surface treatment such as primer application, UV treatment, corona discharge treatment, polishing treatment, and etching treatment as necessary. The dicing tape 11 may have adhesiveness. Such a dicing tape 11 may be one in which adhesiveness is imparted to the plastic film, or one in which an adhesive layer is provided on one surface of the plastic film. The adhesive layer may be formed of an ultraviolet-curable or non-ultraviolet-curable pressure-sensitive adhesive, and is not particularly limited as long as the adhesive layer has sufficient adhesiveness so that the semiconductor element does not scatter during dicing, and conventionally known adhesive layers can be used.

The thickness of the dicing tape 11 may be, for example, 10 to 1000 μm, 30 to 500 μm, or 50 to 300 μm.

The laminate 40 can be obtained by attaching the dicing tape 11 to the semiconductor wafer 1A of the third laminate 30.

Subsequently, in the laminate 40, at least the semiconductor wafer 1A and the resin layer 3 (and a part of the dicing tape 11) are diced to be divided into individual pieces. The dicing may be, for example, dicing by a dicing blade 13. The dicing by the dicing blade 13 can be performed using a commercially available apparatus. The dicing by the dicing blade 13 is performed, for example, on the semiconductor wafer 1A and the resin layer 3 in a cutting pattern forming a lattice shape in plan view. The dicing by the dicing blade 13 may be performed while applying cooling water (cutting water) to the contact portion between the semiconductor wafer 1A or the resin layer 3 and the dicing blade 13 from the viewpoint of suppressing a temperature rise at the contact portion between these contact portions.

The resin layer 3 can act as a protective layer for preventing a cut product (debris) from adhering to the circuit formation surface of the semiconductor wafer.

The dicing may be, for example, plasma dicing, stealth dicing, or laser dicing, instead of blade dicing.

In this way, the semiconductor wafer 1A and the resin layer 3 are singulated, and the resin-layer-piece-attached semiconductor chip 15 including a semiconductor chip 1Aa and a resin layer piece 3a can be obtained.

The shape of the semiconductor chip 1Aa in plan view may be, for example, a square or a rectangle. The area of the semiconductor chip 1a may be, for example, 1 to 250 mm², 4 to 200 mm², or 9 to 150 mm². The length of one side of the semiconductor chip 1a may be 1 mm or more, 2 mm or more, or 3 mm or more, and may be 20 mm or less, 18 mm or less, or 15 mm or less. The thickness of the semiconductor chip 1Aa may be similar to the thickness of the semiconductor wafer 1A.

### <Resin Layer Piece Removing Step>

In this step, the resin in the resin layer piece 3a of the resin-layer-piece-attached semiconductor chip 15 is reacted with water to remove the resin layer piece 3a from the resin-layer-piece-attached semiconductor chip 15. Since the resin A contained in the resin layer piece 3a is reduced in molecular weight by reaction with water, solubility in water is improved, and thus the resin layer piece 3a can be easily removed from the resin-layer-piece-attached semiconductor chip 15 by using water.

Examples of the aqueous solvent include water and a mixed solvent of water and a hydrophilic organic solvent. In the mixed solvent of water and the hydrophilic organic solvent, the ratio of water can be, for example, 80 mass % or more. For example, a pHI adjusting agent may be added to the aqueous solvent.

The aqueous solvent may be water. Examples of water include tap water, natural water, purified water, distilled water, ion-exchanged water, pure water, and ultrapure water (Milli-Q water or the like). The Milli-Q water means ultrapure water obtained by a Milli-Q water production device of Merck Millipore (Merck Co.). Since impurities are reduced, the water may be purified water, distilled water, ion-exchanged water, pure water, or ultrapure water.

Examples of the hydrophilic organic solvent include alcohols such as methanol, ethanol, 2-propanol, and 1,2-propanediol; and glycol ethers such as ethylene glycol monomethyl ether, propylene glycol monomethyl ether, ethyl cellosolve, propylene glycol monopropyl ether, propylene glycol monoisopropyl ether, butyl cellosolve, ethylene glycol monoisobutyl ether, propylene glycol monobutyl ether, diethylene glycol dimethyl ether, diethylene glycol diethyl ether, and dipropylene glycol monomethyl ether.

Examples of the pH adjusting agent include inorganic acids, inorganic bases, organic acids, and organic bases. Examples of the inorganic acid include nitric acid, sulfuric acid, hydrochloric acid, phosphoric acid, and boric acid. Examples of the inorganic base include sodium hydroxide, potassium hydroxide, and calcium hydroxide. Examples of the organic acid include formic acid, acetic acid, propionic acid, butyric acid, acrylic acid, benzoic acid, and picolinic acid. Examples of the organic base include a primary amine, a secondary amine, a tertiary amine, tetramethylammonium hydroxide, tetraethylammonium hydroxide, and an imidazole-based compound.

The temperature of water when the resin is reacted with water may be, for example, 5° C. or more, 10° C. or more, 15° C. or more, 20° C. or more, 25° C. or more, 35° C. or more, 45° C. or more, or 55° C. or more, and may be 80° C. or less, or 70° C. or less. The time until the resin layer piece is dissolved in water can be adjusted by adjusting the temperature of water or the like when the resin and water are reacted. By increasing the temperature of water when the resin is reacted with water, the resin layer piece tends to be dissolved in water in a shorter time.

The time for reacting the resin with water may be, for example, 5 minutes or more, 10 minutes or more, 30 minutes or more, 60 minutes or more, 90 minutes or more, or 120 minutes or more, and may be 150 minutes or less, 120 minutes or less, 90 minutes or less, 60 minutes or less, 45 minutes or less, or 30 minutes or less.

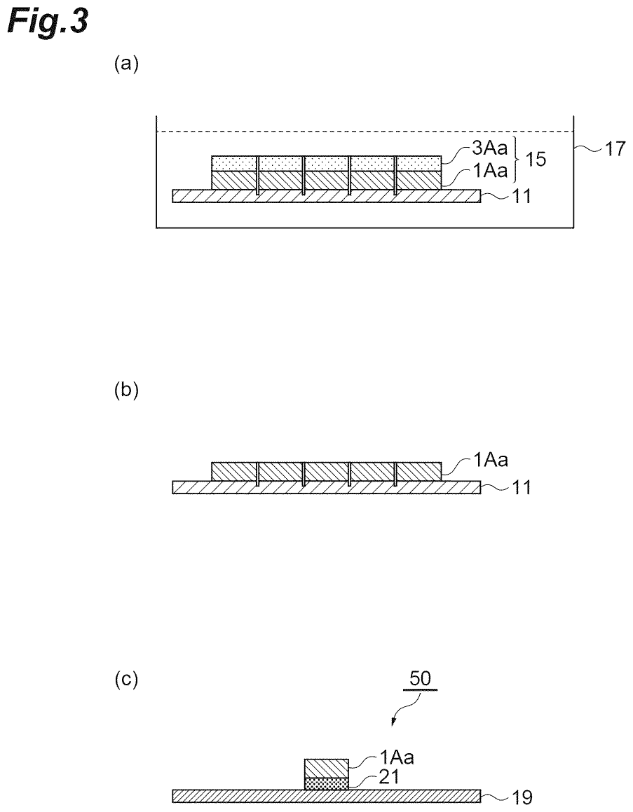

In one embodiment, the resin layer piece removing step may be a step of immersing the resin layer piece 3a from the resin-layer-piece-attached semiconductor chip 15 in an aqueous solvent 17 (see FIG. 3(a)). Since the resin A contained in the resin layer piece 3a is reduced in molecular weight by reaction with water, solubility in water is improved, and therefore the resin A is immersed in the aqueous solvent 17 and flows out to the aqueous solvent 17, so that the resin layer piece 3a can be efficiently removed.

In this way, a plurality of semiconductor chips 1Aa in which adhesion of cut products (debris) is sufficiently suppressed can be obtained from the semiconductor wafer 1A (see FIG. 3(b)).

The method for manufacturing a semiconductor device according to the present embodiment may further include an ultraviolet irradiation step of irradiating the adhesive layer of the dicing tape 11 with ultraviolet rays, a pickup step of picking up the semiconductor chip 1Aa, a semiconductor chip bonding step of thermocompression-bonding the picked-up semiconductor chip 1Aa and a support member 19 with an adhesive layer 21 (die-bonding film or the like) interposed therebetween, and a thermosetting step of thermosetting the adhesive layer 21.

### <Ultraviolet Irradiation Step>

In a case where the adhesive layer of the dicing tape 11 is formed of an ultraviolet curable pressure-sensitive adhesive, the method for manufacturing a semiconductor device may include an ultraviolet irradiation step. In this step, the adhesive layer is irradiated with ultraviolet rays. In the ultraviolet irradiation, the wavelength of the ultraviolet ray may be 200 to 400 nm. In the ultraviolet irradiation condition, the illuminance and the irradiation amount may be in a range of 30 to 240 m W/cm² and a range of 50 to 500 mJ/cm², respectively.

### <Pickup Step>

In this step, the semiconductor chip 1Aa pushed up by the needle from the dicing tape 11 side is sucked by a suction collet and picked up from the dicing tape 11 while separating the diced semiconductor chips 1Aa from each other.

The ultraviolet irradiation step and the pickup step may be performed after the resin layer piece removing step, or may be performed before the resin layer piece removing step.

### <Semiconductor Chip Bonding Step>

In this step, the picked-up semiconductor chip 1Aa and the support member 19 are bonded to each other by thermocompression bonding via the adhesive layer 21 (die-bonding film or the like). As the die-bonding film, a die-bonding film used in the art can be used. A plurality of semiconductor chips 1Aa may be bonded to the support member 19.

The heating temperature in thermocompression bonding may be, for example, 80 to 160° C. The load in thermocompression bonding may be, for example, 5 to 15 N. The heating time in thermocompression bonding may be, for example, 0.5 to 20 seconds.

### <Thermosetting Step>

In this step, the adhesive layer 21 is thermally cured. The heating temperature can be appropriately changed depending on the components of the die-bonding film. The heating temperature may be, for example, 60 to 200° C., 90 to 190° C., or 120 to 180° C. The heating time may be 30 minutes to 5 hours, 1 to 3 hours, or 2 to 3 hours. The temperature or pressure may be changed stepwise.

In this way, a semiconductor device 50 (see FIG. 3(c)) including the semiconductor chip 1Aa, the support member 19 on which the semiconductor chip 1Aa is mounted, and the adhesive layer 21 provided between the semiconductor chip 1Aa and the support member 19 and bonding the semiconductor chip 1Aa and the support member 19 can be manufactured.

### REFERENCE SIGNS LIST

1, 1A Semiconductor wafer
1Aa Semiconductor chip
3 Resin layer
3a Resin layer piece
5 Base material layer
7 Back grinding tape
9 Grinder
10 First laminate
11 Dicing tape
13 Dicing blade
15 Resin-layer-piece-attached semiconductor chip
17 Aqueous solvent
19 Support member
20 Second laminate
21 Adhesive layer
30 Third laminate
40 Laminate
50 Semiconductor device

1. A method for manufacturing a semiconductor device, the method comprising:
a first laminate manufacturing step of manufacturing a first laminate including a semiconductor wafer, a resin layer containing a resin reduced in molecular weight by reaction with water, and a base material layer;
a second laminate manufacturing step of subjecting the semiconductor wafer of the first laminate to back-surface grinding to manufacture a second laminate; and
a third laminate manufacturing step of removing the base material layer of the second laminate to manufacture a third laminate including the semiconductor wafer subjected to back-surface grinding and the resin layer.

2. The method for manufacturing a semiconductor device according to claim 1, further comprising
a resin-layer-piece-attached semiconductor chip manufacturing step of manufacturing a diced resin-layer-piece-attached semiconductor chip by dicing the third laminate.

3. The method for manufacturing a semiconductor device according to claim 2, further comprising
a resin layer piece removing step of reacting the resin in a resin layer piece of the resin-layer-piece-attached semiconductor chip with water to remove the resin layer piece from the resin-layer-piece-attached semiconductor chip.
